(19) United States
(12) Patent Application Publication
(10) Pub. No.: US 2024/0072170 A1
(43) Pub. Date: Feb. 29, 2024

(54) SEMICONDUCTOR DEVICES AND METHODS OF MANUFACTURING THEREOF

(71) Applicant: Taiwan Semiconductor Manufacturing Company, Ltd., Hsinchu (TW)

(72) Inventors: Li-Wei Yin, Hsinchu (TW); Tzu-Wen Pan, Hsinchu (TW); Yu-Hsien Lin, Kaohsiung (TW); Yu-Shih Wang, Hsinchu (TW); Yih-Ann Lin, Hsinchu (TW); Chia Ming Liang, Hsinchu (TW); Ryan Chia-Jen CHEN, Hsinchu (TW)

(73) Assignee: Taiwan Semiconductor Manufacturing Company, Ltd., Hsinchu (TW)

(21) Appl. No.: 17/894,614

(22) Filed: Aug. 24, 2022

(51) Int. Cl. H01L 29/78; H01L 29/66

(52) U.S. Cl. CPC H01L 29/7851; H01L 29/66545; H01L 29/6656; H01L 29/66795

(57) ABSTRACT

A semiconductor device is disclosed. The semiconductor device includes a semiconductor fin. The semiconductor device includes first spacers over the semiconductor fin. The semiconductor device includes a metal gate structure, over the semiconductor fin, that is sandwiched at least by the first spacers. The semiconductor device includes a gate electrode contacting the metal gate structure. An interface between the metal gate structure and the gate electrode has its side portions extending toward the semiconductor fin with a first distance and a central portion extending toward the semiconductor fin with a second distance, the first distance being substantially less than the second distance.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of a fin field-effect transistor (FinFET) device, in accordance with some embodiments.

FIG. 2 illustrates a flow chart of an example method for making a non-planar transistor device, in accordance with some embodiments.

FIGS. 3, 4, 5, 6, 7, 8, 9, 10, 11, 12, 13, 14, 15, 16, and 17 illustrate cross-sectional views of an example FinFET device (or a portion of the example FinFET device) during various fabrication stages, made by the method of FIG. 2, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, the active (e.g., metal) gate structure of a transistor device (e.g., a FinFET, a gate-all-around (GAA) transistor, etc.) can be formed by replacing a dummy (e.g., polysilicon) gate structure. Such a metal gate structure can have plural work function metals stacked on top of one another. By combining different work function metals, various threshold voltages for the resultant transistor device can be achieved. In existing technologies, after depositing plural work function metals, it is typically challenging to tune the threshold voltage by adjusting (e.g., etching) only one of the work functions metals. As such, the threshold voltage may not be accurately controlled. Thus, the existing technologies for forming the metal gate structure of a transistor device have not been entirely satisfactory in many aspects.

The present disclosure provides various embodiments of a transistor device that has its metal gate structure formed without the above-identified issues. In various embodiments, the metal gate structure, as disclosed herein, may have a number of work function metals stacked on top of one another. The work function metals can have respective different conductive types. After depositing the work function metals, at least one selective etching process can be performed to etch one of the work function metals, while leaving other work functions metals substantially intact. As such, a height (or thickness) of the metal gate structure can be maintained, which can advantageously lower an effective resistance of the metal gate structure. Further, a threshold voltage of the resultant transistor device can be tuned by adjusting only one of the work function metals, which advantageously allows the threshold voltage to be accurately tuned. As a result of etching one of the work function metals, the work function metals can present different heights. A later deposited gate electrode can inherit the profiles of the work function metals in different heights, which causes the gate electrode to have a “tiger tooth” profile. For example, such a tiger tooth profile can have its first (e.g., side) portions downwardly extending with a longer distance and its second (e.g., central) portion downwardly extending with a shorter distance.

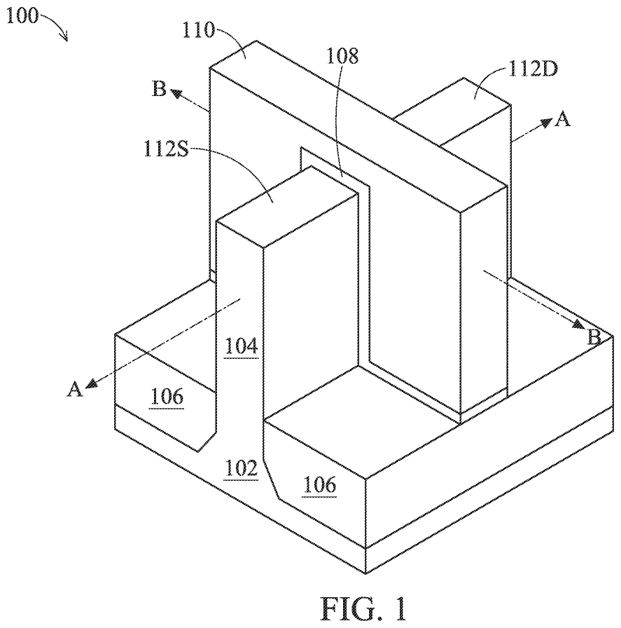

FIG. 1 illustrates a perspective view of an example FinFET device 100, in accordance with various embodiments. The FinFET device 100 includes a substrate 102 and a fin 104 protruding above the substrate 102. Isolation regions 106 are formed on opposing sides of the fin 104, with the fin 104 protruding above the isolation regions 106. A gate dielectric 108 is along sidewalls and over a top surface of the fin 104, and a gate 110 is over the gate dielectric 108. Source/drain regions 112D and 112S are in the fin 104 and on opposing sides of the gate dielectric 108 and the gate 110. A source/drain region may refer to a source or a drain, individually or collectively, dependent upon the context. The source/drain regions 112D and 112S extend outward from the gate 110. FIG. 1 is provided as a reference to illustrate a number of cross-sections in subsequent figures. For example, cross-section B-B extends along a longitudinal axis of the gate 110 of the FinFET device 100. Cross-section A-A is perpendicular to cross-section B-B and is along a longitudinal axis of the fin 104 and in a direction of, for example, a current flow between the source/drain regions 112S/112D. Subsequent figures refer to these reference cross-sections for clarity.

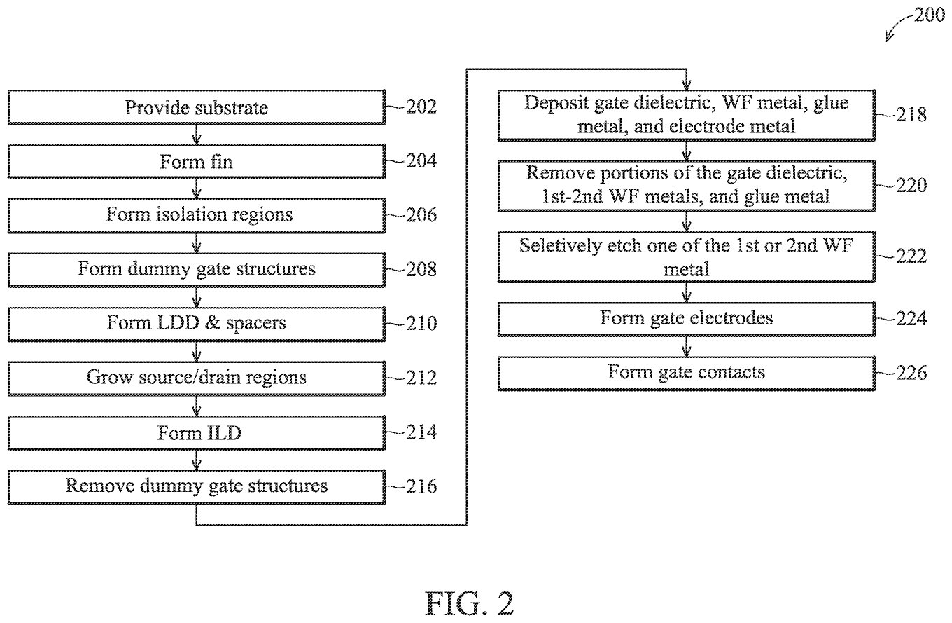

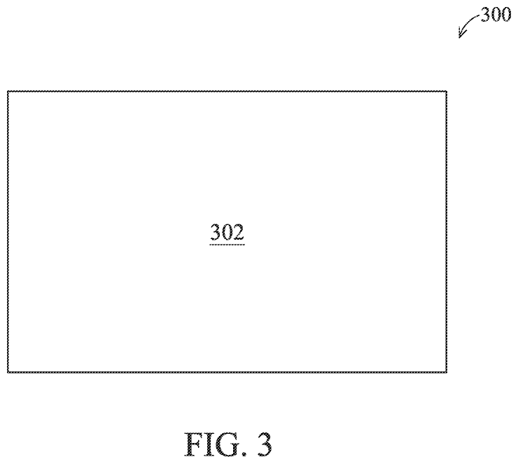

FIG. 2 illustrates a flowchart of a method 200 to form a non-planar transistor device, according to one or more embodiments of the present disclosure. For example, at least some of the operations of the method 200 can be used to form a FinFET device (e.g., FinFET device 100), a nanosheet transistor device, a gate-all-around transistor device, a nanowire transistor device, a vertical transistor, or the like. It is noted that the method 200 is merely an example, and is not intended to limit the present disclosure. Accordingly, it is understood that additional operations may be provided before, during, and after the method 200 of FIG. 2, and that some other operations may only be briefly described herein. In some embodiments, operations of the method 200 may be associated with cross-sectional views of an example FinFET device at various fabrication stages as shown in FIGS. 3, 4, 5, 6, 7, 8, 9, 10, 11, 12, 13, 14, 15, 16, and 17, respectively, which will be discussed in further detail below.

In brief overview, the method 200 starts with operation 202 of providing a substrate. The method 200 continues to operation 204 of forming a fin. The method 200 continues to operation 206 of forming isolation regions. The method 200 continues to operation 208 of forming dummy gate structures. The dummy gate structures may straddle a (e.g., central) portion of the fin. The method 200 continues to operation 210 of forming lightly doped drain (LDD) regions and gate spacers. The gate spacers are extended along sidewalls of the dummy gate structure. The method 200 continues to operation 212 of growing source/drain regions. The method 200 continues to operation 214 of forming an interlayer dielectric (ILD). The method 200 continues to operation 216 of removing the dummy gate structures. Upon the dummy gate structure being removed, the overlaid portion of the fin can be re-exposed. The method 200 continues to operation 218 of depositing a gate dielectric, a first work function metal, a second work function metal, and a glue metal. The method 200 continues to operation 220 of removing a portion of the glue metal, a portion of the first work function metal, a portion of the second work function metal, and a portion of the glue metal. The method 200 continues to operation 222 of selectively etching one of the first or second work function metal. The method 200 continues to operation 224 of forming gate electrodes. The method 200 continues to operation 226 of forming gate contacts.

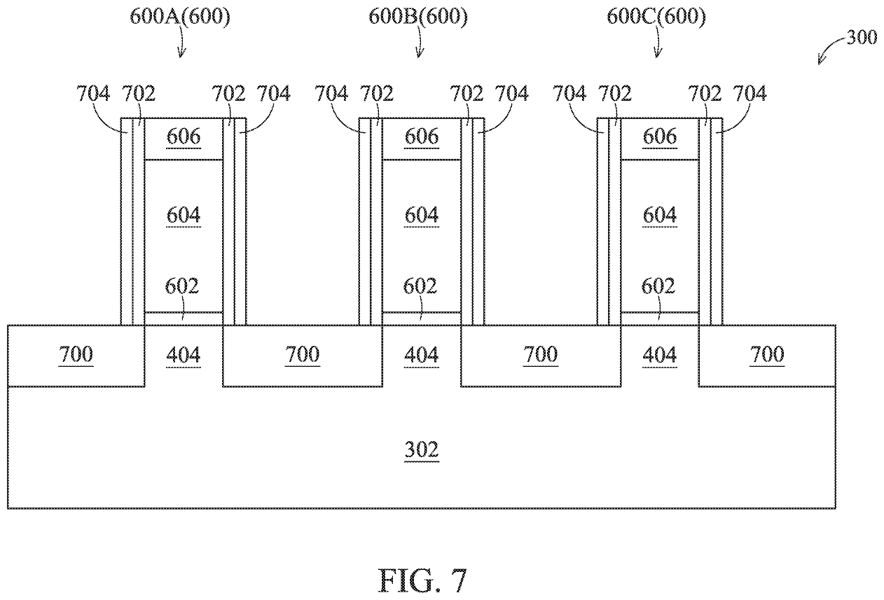

As mentioned above, FIGS. 3-17 each illustrates, in a cross-sectional view, a portion of a FinFET device 300 at various fabrication stages of the method 200 of FIG. 2. The FinFET device 300 is substantially similar to the FinFET device 100 shown in FIG. 1, but with multiple gate structures. For example, FIGS. 3-6 illustrate cross-sectional views of the FinFET device 300 along cross-section B-B (as indicated in FIG. 1); and FIG. 7-17 illustrate cross-sectional views of the FinFET device 300 along cross-section A-A (as indicated in FIG. 1). Although FIGS. 3-17 illustrate the FinFET device 300, it is understood the FinFET device 300 may include a number of other devices such as inductors, fuses, capacitors, coils, etc., which are not shown in FIGS. 3-17, for purposes of clarity of illustration.

Corresponding to operation 202 of FIG. 2, FIG. 3 is a cross-sectional view of the FinFET device 300 including a semiconductor substrate 302 at one of the various stages of fabrication. The substrate 302 may be a semiconductor substrate, such as a bulk semiconductor, a semiconductor-on-insulator (SOI) substrate, or the like, which may be doped (e.g., with a p-type or an n-type dopant) or undoped. The substrate 302 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 302 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

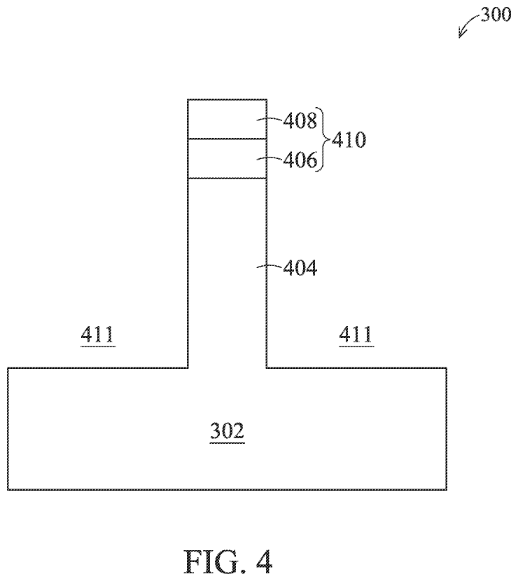

Corresponding to operation 204 of FIG. 2, FIG. 4 is a cross-sectional view of the FinFET device 300 including a (semiconductor) fin 404 at one of the various stages of fabrication. Although one fin is shown in the illustrated embodiment of FIG. 4 (and the following figures), it should be appreciated that the FinFET device 300 can include any number of fins while remaining within the scope of the present disclosure. In some embodiments, the fin 404 is formed by patterning the substrate 302 using, for example, photolithography and etching techniques. For example, a mask layer, such as a pad oxide layer 406 and an overlying pad nitride layer 408, is formed over the substrate 302. The pad oxide layer 406 may be a thin film comprising silicon oxide formed, for example, using a thermal oxidation process. The pad oxide layer 406 may act as an adhesion layer between the substrate 302 and the overlying pad nitride layer 408. In some embodiments, the pad nitride layer 408 is formed of silicon nitride, silicon oxynitride, silicon carbonitride, the like, or combinations thereof. The pad nitride layer 408 may be formed using low-pressure chemical vapor deposition (LPCVD) or plasma enhanced chemical vapor deposition (PECVD), for example.

The mask layer may be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. For example, the photoresist material is used to pattern the pad oxide layer 406 and pad nitride layer 408 to form a patterned mask 410, as illustrated in FIG. 4.

The patterned mask 410 is subsequently used to pattern exposed portions of the substrate 302 to form trenches (or openings) 411, thereby defining a fin 404 between adjacent trenches 411 as illustrated in FIG. 4. When multiple fins are formed, such a trench may be disposed between any adjacent ones of the fins. In some embodiments, the fin 404 is formed by etching trenches in the substrate 302 using, for example, reactive ion etch (RIE), neutral beam etch (NBE), the like, or combinations thereof. The etching may be anisotropic. In some embodiments, the trenches 411 may be strips (viewed from the top) parallel to each other, and closely spaced with respect to each other. In some embodiments, the trenches 411 may be continuous and surround the fin 404. The fin 404 may also be referred to as fin 404 hereinafter.

The fin 404 may be patterned by any suitable method. For example, the fin 404 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fin.

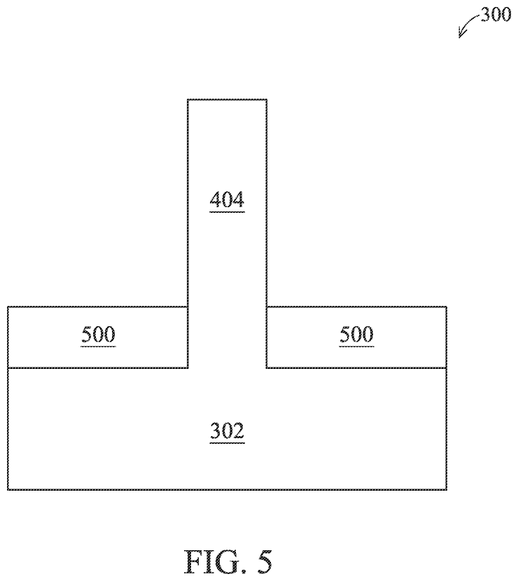

Corresponding to operation 206 of FIG. 2, FIG. 5 is a cross-sectional view of the FinFET device 300 including isolation regions 500 at one of the various stages of fabrication. The isolation regions 500, which are formed of an insulation material, can electrically isolate neighboring fins from each other. The insulation material may be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used. In the illustrated embodiment, the insulation material is silicon oxide formed by a FCVD process. An anneal process may be performed once the insulation material is formed. A planarization process, such as a chemical mechanical polish (CMP), may remove any excess insulation material and form top surfaces of the isolation regions 500 and a top surface of the fin 404 that are coplanar (not shown, the isolation regions 500 will be recessed as shown in FIG. 5). The patterned mask 410 (FIG. 4) may also be removed by the planarization process.

In some embodiments, the isolation regions 500 include a liner, e.g., a liner oxide (not shown), at the interface between each of the isolation regions 500 and the substrate 302 (fin 404). In some embodiments, the liner oxide is formed to reduce crystalline defects at the interface between the substrate 302 and the isolation region 500. Similarly, the liner oxide may also be used to reduce crystalline defects at the interface between the fin 404 and the isolation region 500. The liner oxide (e.g., silicon oxide) may be a thermal oxide formed through a thermal oxidation of a surface layer of the substrate 302, although other suitable method may also be used to form the liner oxide.

Next, the isolation regions 500 are recessed to form shallow trench isolation (STI) regions 500, as shown in FIG. 5. The isolation regions 500 are recessed such that the upper portions of the fin 404 protrude from between neighboring STI regions 500. Respective top surfaces of the STI regions 500 may have a flat surface (as illustrated), a convex surface, a concave surface (such as dishing), or combinations thereof. The top surfaces of the STI regions 500 may be formed flat, convex, and/or concave by an appropriate etch. The isolation regions 500 may be recessed using an acceptable etching process, such as one that is selective to the material of the isolation regions 500. For example, a dry etch or a wet etch using dilute hydrofluoric (DHF) acid may be performed to recess the isolation regions 500.

FIGS. 3 through 5 illustrate an embodiment of forming one or more fins (such as fin 404), but a fin may be formed in various different processes. For example, a top portion of the substrate 302 may be replaced by a suitable material, such as an epitaxial material suitable for an intended type (e.g., n-type or p-type) of semiconductor devices to be formed. Thereafter, the substrate 302, with epitaxial material on top, is patterned to form the fin 404 that includes the epitaxial material.

As another example, a dielectric layer can be formed over a top surface of a substrate; trenches can be etched through the dielectric layer; homoepitaxial structures can be epitaxially grown in the trenches; and the dielectric layer can be recessed such that the homoepitaxial structures protrude from the dielectric layer to form one or more fins.

In yet another example, a dielectric layer can be formed over a top surface of a substrate; trenches can be etched through the dielectric layer; heteroepitaxial structures can be epitaxially grown in the trenches using a material different from the substrate; and the dielectric layer can be recessed such that the heteroepitaxial structures protrude from the dielectric layer to form one or more fins.

In embodiments where epitaxial material(s) or epitaxial structures (e.g., the heteroepitaxial structures or the homoepitaxial structures) are grown, the grown material(s) or structures may be in situ doped during growth, which may obviate prior and subsequent implantations although in situ and implantation doping may be used together. Still further, it may be advantageous to epitaxially grow a material in an NMOS region different from the material in a PMOS region. In various embodiments, the fin 404 may include silicon germanium (SiₓGe₁₋ₓ, where x can be between 0 and 1), silicon carbide, pure or substantially pure germanium, a III-V compound semiconductor, a II-VI compound semiconductor, or the like. For example, the available materials for forming III-V compound semiconductor include, but are not limited to, InAs, AlAs, GaAs, InP, GaN, InGaAs, InAlAs, GaSb, AlSb, AlP, GaP, and the like.

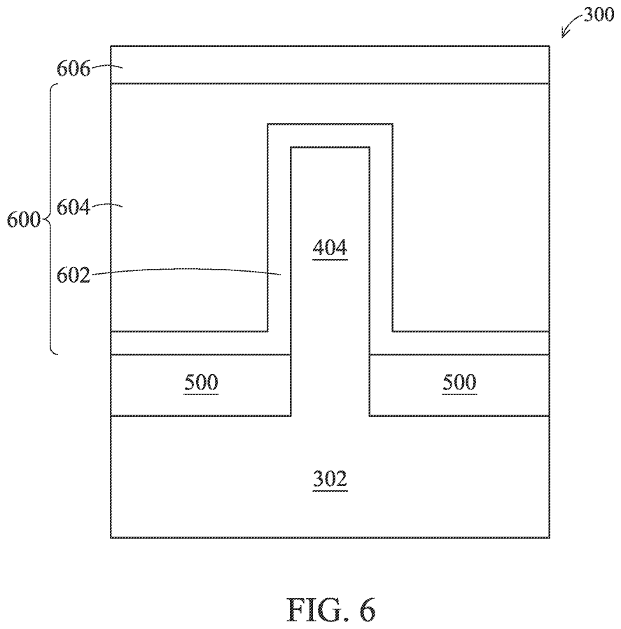

Corresponding to operation 208 of FIG. 2, FIG. 6 is a cross-sectional view of the FinFET device 300 including a dummy gate structure 600 at one of the various stages of fabrication. The dummy gate structure 600 includes a dummy gate dielectric 602 and a dummy gate 604, in some embodiments. A mask 606 may be formed over the dummy gate structure 600. To form the dummy gate structure 600, a dielectric layer is formed on the fin 404. The dielectric layer may be, for example, silicon oxide, silicon nitride, multilayers thereof, or the like, and may be deposited or thermally grown.

A gate layer is formed over the dielectric layer, and a mask layer is formed over the gate layer. The gate layer may be deposited over the dielectric layer and then planarized, such as by a CMP. The mask layer may be deposited over the gate layer. The gate layer may be formed of, for example, polysilicon, although other materials may also be used. The mask layer may be formed of, for example, silicon nitride or the like.

After the layers (e.g., the dielectric layer, the gate layer, and the mask layer) are formed, the mask layer may be patterned using acceptable photolithography and etching techniques to form the mask 606. The pattern of the mask 606 then may be transferred to the gate layer and the dielectric layer by an acceptable etching technique to form the dummy gate 604 and the underlying dummy gate dielectric 602, respectively. The dummy gate 604 and the dummy gate dielectric 602 cover a central portion (e.g., a channel region) of the fin 404. The dummy gate 604 may also have a lengthwise direction (e.g., direction B-B of FIG. 1) substantially perpendicular to the lengthwise direction (e.g., direction of A-A of FIG. 1) of the fin 404.

The dummy gate dielectric 602 is shown to be formed over the fin 404 (e.g., over top surfaces and sidewalls of the fin 404) and over the STI regions 500 in the example of FIG. 6. In other embodiments, the dummy gate dielectric 602 may be formed by, e.g., thermal oxidization of a material of the fin 404, and therefore, may be formed over the fin 404 but not over the STI regions 500. It should be appreciated that these and other variations are still included within the scope of the present disclosure.

FIGS. 7-17 illustrate the cross-sectional views of further processing (or making) of the FinFET device 300 along cross-section A-A (along a longitudinal axis of the fin 404), as shown in FIG. 1. In brief overview, three dummy gate structures 600A, 600B, and 600C are illustrated over the fin 404 in the examples of FIGS. 7-11. For simplicity, the dummy gate structures 600A, 600B, and 600C may sometimes be collectively referred to as dummy gate structures 600. It should be appreciated that more or less than three dummy gate structures can be formed over the fin 404, while remaining within the scope of the present disclosure.

Corresponding to operation 210 of FIG. 2, FIG. 7 is a cross-sectional view of the FinFET device 300 including a number of lightly doped drain (LDD) regions 700 formed in the fin 404 at one of the various stages of fabrication. The LDD regions 700 may be formed by a plasma doping process. The plasma doping process may include forming and patterning masks such as a photoresist to cover the regions of the FinFET device 300 that are to be protected from the plasma doping process. The plasma doping process may implant n-type or p-type impurities in the fin 404 to form the LDD regions 700. For example, p-type impurities, such as boron, may be implanted in the fin 404 to form the LDD regions 700 for a p-type device. In another example, n-type impurities, such as phosphorus, may be implanted in the fin 404 to form the LDD regions 700 for an n-type device. In some embodiments, the LDD regions 700 abut one of the channel regions of the FinFET device 300 (e.g., the central portion of the fin 404 overlaid by one of the dummy structures 600). Portions of the LDD regions 700 may extend under the dummy gate structure 600 and into the channel region of the FinFET device 300. FIG. 7 illustrates a non-limiting example of the LDD regions 700. Other configurations, shapes, and formation methods of the LDD regions 700 are also possible and are fully intended to be included within the scope of the present disclosure. For example, the LDD regions 700 may be formed after gate spacers 702/704, which will be discussed below, are formed. In some embodiments, the LDD regions 700 are omitted.

Still referring to FIG. 7, after the LDD regions 700 are formed, in some embodiments, first gate spacers 702 are formed around (e.g., along and contacting the sidewalls of) the dummy gate structures 600, and second gate spacers 704 are formed around (e.g., along and contacting the sidewalls of) the first gate spacers 702. For example, the first gate spacer 702 may be formed on opposing sidewalls of the dummy gate structure 600. The second gate spacer 704 may be formed on the first gate spacer 702. It should be understood that any number of gate spacers can be formed around the dummy gate structures 600 while remaining within the scope of the present disclosure.

The first gate spacer 702 may be a low-k spacer and may be formed of a suitable dielectric material, such as silicon oxide, silicon oxycarbonitride, or the like. The second gate spacer 704 may be formed of a nitride, such as silicon nitride, silicon oxynitride, silicon carbonitride, the like, or combinations thereof. Any suitable deposition method, such as thermal oxidation, chemical vapor deposition (CVD), or the like, may be used to form the first gate spacer 702 and the second gate spacer 704. In accordance with various embodiments, the first gate spacer 702 and the second gate spacer 704 are formed of different materials to provide etching selectivity in subsequent processing. The first gate spacer 702 and the second gate spacer 704 may sometimes be collectively referred to as gate spacers 702/704.

The shapes and formation methods of the gate spacers 702-704 as illustrated in FIG. 7 (and the following figures) are merely non-limiting examples, and other shapes and formation methods are possible. These and other variations are fully intended to be included within the scope of the present disclosure.

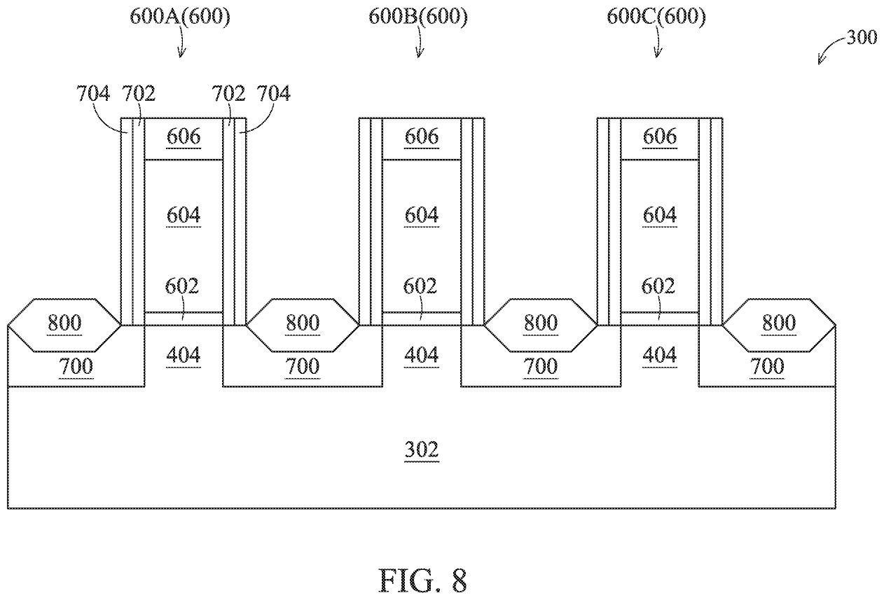

Corresponding to operation 212 of FIG. 2, FIG. 8 is a cross-sectional view of the FinFET device 300 including a number of source/drain regions 800 at one of the various stages of fabrication. The source/drain regions 800 are formed in recesses of the fin 404 adjacent to the dummy gate structures 600. For example, the source/drain regions 800 and the dummy gate structures 600 are alternately arranged. In other words, one source/drain region 800 is sandwiched between adjacent dummy gate structures 600 and/or merely one side of the source/drain region 800 is disposed next to a dummy gate structure 600. The recesses are formed by, e.g., an anisotropic etching process using the dummy gate structures 600 as an etching mask, in some embodiments, although any other suitable etching process may also be used.

The source/drain regions 800 are formed by epitaxially growing a semiconductor material in the recess, using suitable methods such as metal-organic CVD (MOCVD), molecular beam epitaxy (MBE), liquid phase epitaxy (LPE), vapor phase epitaxy (VPE), selective epitaxial growth (SEG), the like, or a combination thereof.

As illustrated in FIG. 8, the epitaxial source/drain regions 800 may have surfaces raised from respective surfaces of the fin 404 (e.g. raised above the non-recessed portions of the fin 404) and may have facets. In some embodiments, the source/drain regions 800 of the adjacent fins may merge to form a continuous epitaxial source/drain region (not shown). In some embodiments, the source/drain regions 800 of the adjacent fins may not merge together and remain separate source/drain regions 800 (not shown). In some embodiments, when the resulting FinFET device is an n-type FinFET, the source/drain regions 800 can include silicon carbide (SiC), silicon phosphorous (SiP), phosphorous-doped silicon carbon (SiCP), or the like. In some embodiments, when the resulting FinFET device is a p-type FinFET, the source/drain regions 800 comprise SiGe, and a p-type impurity such as boron or indium.

The epitaxial source/drain regions 800 may be implanted with dopants to form source/drain regions 800 followed by an annealing process. The implanting process may include forming and patterning masks such as a photoresist to cover the regions of the FinFET device 300 that are to be protected from the implanting process. The source/drain regions 800 may have an impurity (e.g., dopant) concentration in a range from about 1×10¹⁹ cm⁻³ to about 1×10²¹ cm⁻³. P-type impurities, such as boron or indium, may be implanted in the source/drain region 800 of a p-type transistor. N-type impurities, such as phosphorous or arsenide, may be implanted in the source/drain regions 800 of an n-type transistor. In some embodiments, the epitaxial source/drain regions 800 may be in situ doped during their growth.

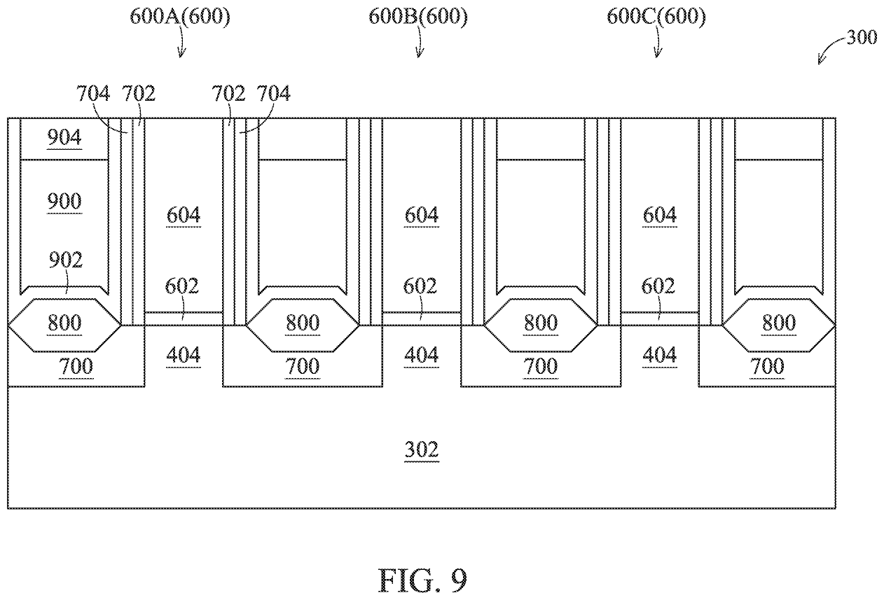

Corresponding to operation 214 of FIG. 2, FIG. 9 is a cross-sectional view of the FinFET device 300 including an interlayer dielectric (ILD) 900 at one of the various stages of fabrication. In some embodiments, prior to forming the ILD 900, a contact etch stop layer (CESL) 902 is formed over the structure illustrated in FIG. 9. The CESL 902 can function as an etch stop layer in a subsequent etching process, and may comprise a suitable material such as silicon oxide, silicon nitride, silicon oxynitride, combinations thereof, or the like, and may be formed by a suitable formation method such as CVD, PVD, combinations thereof, or the like.

Next, the ILD 900 is formed over the CESL 902 and over the dummy gate structures 600 (e.g., 600A, 600B, and 600C). In some embodiments, the ILD 900 is formed of a dielectric material such as silicon oxide, phosphosilicate glass (PSG), borosilicate glass (BSG), boron-doped phosphosilicate Glass (BPSG), undoped silicate glass (USG), or the like, and may be deposited by any suitable method, such as CVD, PECVD, or FCVD. After the ILD 900 is formed, a dielectric layer 904 is formed over the ILD 900. The dielectric layer 904 can function as a protection layer to prevent or reduces the loss of the ILD 900 in subsequent etching processes. The dielectric layer 904 may be formed of a suitable material, such as silicon nitride, silicon carbonitride, or the like, using a suitable method such as CVD, PECVD, or FCVD. After the dielectric layer 904 is formed, a planarization process, such as a CMP process, may be performed to achieve a level upper surface for the dielectric layer 904. The CMP may also remove the mask 606 and portions of the CESL 902 disposed over the dummy gate 604. After the planarization process, the upper surface of the dielectric layer 904 is level with the upper surface of the dummy gate 604, in some embodiments.

An example gate-last process (sometimes referred to as replacement gate process) is performed subsequently to replace the dummy gate 604 and the dummy gate dielectric 602 of each of the dummy gate structures 600 with an active gate (which may also be referred to as a replacement gate or a metal gate).

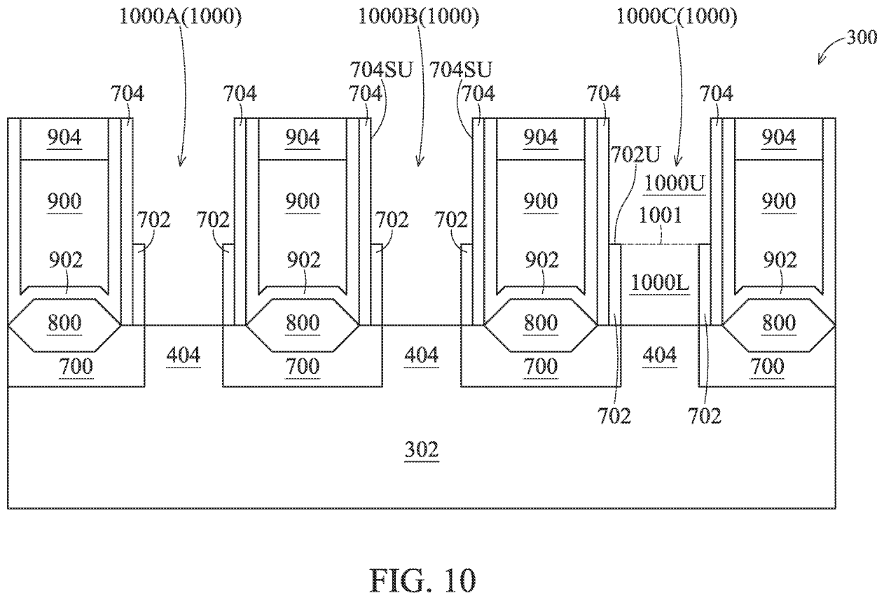

Corresponding to operation 216 of FIG. 2, FIG. 10 is a cross-sectional view of the FinFET device 300 in which the dummy gate structures 600A, 600B, and 600C (FIG. 9) are removed to form gate trenches 1000A, 1000B, and 1000C, respectively, at one of the various stages of fabrication. Next, upper portions of the gate trenches 1000A, 1000B, and 1000C are horizontally expanded by removing relative upper portions of the first gate spacers 702, such that each of the gate trenches 1000A, 1000B, and 1000C has an upper trench 1000U and a lower trench 1000L, where the upper trench 1000U is wider than the lower trench 1000L horizontally. Details of forming the gate trenches 1000A-C will be discussed below. For simplicity, the gate trenches 1000A-C may sometimes be collectively referred to as gate trenches 1000.

In some embodiments, to remove the dummy gate structures 600, one or more etching steps are performed to remove the dummy gate 604 and the dummy gate dielectric 602 directly under the dummy gate 604, so that the gate trenches 1000 (which may also be referred to as recesses) are formed between respective first gate spacers 702. Each gate trench 1000 exposes the channel region of the fin 404. During the dummy gate removal, the dummy gate dielectric 602 may be used as an etch stop layer when the dummy gate 604 is etched. The dummy gate dielectric 602 may then be removed after the removal of the dummy gate 604.

Next, an anisotropic etching process, such as a dry etch process, is performed to remove upper portions of the first gate spacer 702. In some embodiments, the anisotropic etching process is performed using an etchant that is selective to (e.g., having a higher etching rate for) the material of the first gate spacer 702, such that the first gate spacer 702 is recessed (e.g., upper portions removed) without substantially attacking the second gate spacer 704 and the dielectric layer 904. After the upper portions of the first gate spacers 702 are removed, upper sidewalls 704SU of the second gate spacer 704 are exposed.

As illustrated in FIG. 10, after the upper portions of the first gate spacers 702 are removed, each of the gate trenches 1000 has an upper trench 1000U and a lower trench 1000L. The lower trench 1000L is between the remaining lower portions of the first gate spacer 702. The upper trench 1000U is over the lower trench, and is defined (e.g., bordered) by the upper sidewalls 704SU of the second gate spacer 704. FIG. 10 illustrates a symbolic interface 1001 between the upper trench 1000U and the lower trench 1000L. The interface 1001 is level with an upper surface 1000U of the remaining lower portions of the first gate spacer 702.

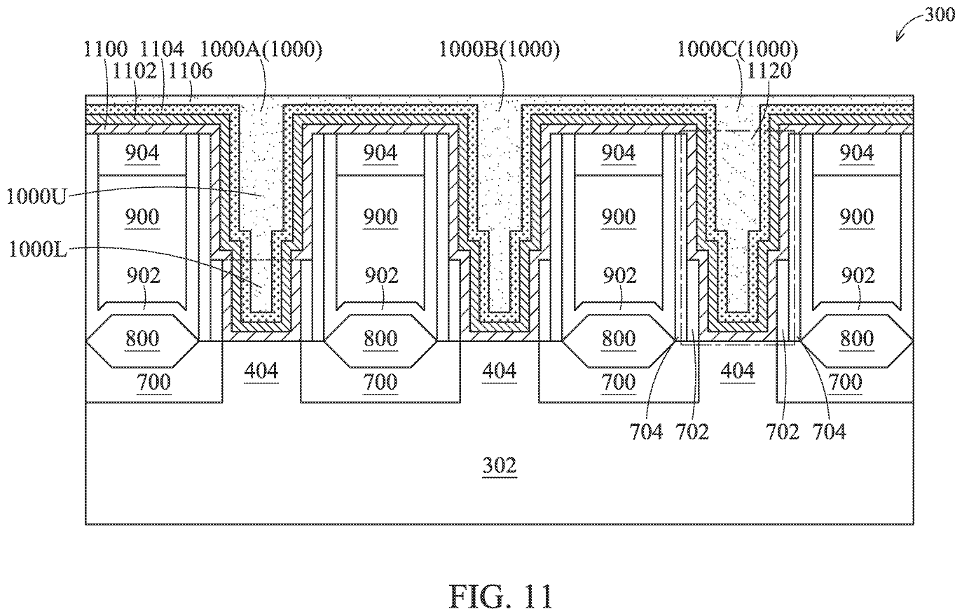

Corresponding to operation 218 of FIG. 2, FIG. 11 is a cross-sectional view of the FinFET device 300 including a gate dielectric (layer) 1100, a first work function metal (layer) 1102, a second work function metal (layer) 1104, and a glue metal (layer) 1106 at one of the various stages of fabrication.

The gate dielectric 1100, the first work function metal 1102, the second work function metal 1104, and the glue metal 1106 are formed successively in the gate trenches 1000. In the illustrated example of FIG. 11, the gate dielectric 1100 is formed to line the gate trench 1100, the first work function metal 1102 is formed to line the gate dielectric 1100, and the second work function metal 1104 is formed to line the first work function metal 1102, with the glue metal 1106 filling a remaining portion of the gate trench 1000. As such, at least in the lower trench 1000L, the gate dielectric 1100, the first work function metal 1102, and the second work function metal 1104 can each have a U-shaped profile, where the U-shaped profile of the second work function metal 1104 is enclosed by the U-shaped profile of the first work function metal 1102. In some embodiments, the glue metal 1106 can fill both the lower trench 1000L and the upper trench 1000U, as shown in FIG. 11.

For example, the gate dielectric 1100 is deposited (e.g., conformally) in the gate trench 1000, such as on the top surfaces and the sidewalls of the fin 404, on the top surfaces and the sidewalls of the gate spacers 702/704, and on the top surface of the dielectric layer 904. In accordance with some embodiments, the gate dielectric 1100 includes silicon oxide, silicon nitride, or multilayers thereof. In example embodiments, the gate dielectric 1100 includes a high-k dielectric material, and in these embodiments, the gate dielectric 1100 may have a k value (dielectric constant) greater than about 7.0, and may include a metal oxide or a silicate of Hf, Al, Zr, La, Mg, Ba, Ti, Pb, and combinations thereof. The formation methods of gate dielectric 1100 may include molecular beam deposition (MBD), atomic layer deposition (ALD), PECVD, and the like. A thickness of the gate dielectric 1100 may be between about 8 angstroms (Å) and about 20 angstroms, as an example. A thickness of the gate dielectric 1100 may be between about 5 nanometer (nm) and about 25 nm, as another example.

Next, the first work function metal 1102 is deposited (e.g., conformally) over the gate dielectric 1100, with the second work function metal 1104 deposited (e.g., conformally) over the first work function metal 1102. In some embodiments, the first work function metal 1102 may be a p-type work function layer, and the second work function metal 1104 may be an n-type work function layer. In some other embodiments, the first work function metal 1102 may be an n-type work function layer, and the second work function metal 1104 may be a p-type work function layer. In the discussion herein, a work function layer may also be referred to as a work function metal.

Example p-type work function metals that may be included in the gate structures for p-type devices include TiN, TaN, Ru, Mo, Al, WN, ZrSi₂, MoSi₂, TaSi₂, NiSi₂, WCN, other suitable p-type work function materials, or combinations thereof. Example n-type work function metals that may be included in the gate structures for n-type devices include Ti, Ag, TaAl, TaAlC, TiAlN, TaC, TaCN, TaSiN, Mn, Zr, other suitable n-type work function materials, or combinations thereof. A work function value is associated with the material composition of the work function layer, and thus, the material of the work function layer is chosen to tune its work function value so that a target threshold voltage Vₜ is achieved in the device that is to be formed. The work function metal may be deposited by CVD, physical vapor deposition (PVD), ALD, and/or other suitable process. A thickness of a p-type work function layer may be between about 8 Å and about 15 Å, and a thickness of an n-type work function layer may be between about 15 Å and about 30 Å, as an example. A thickness of the p-type work function layer (e.g., first work function metal 1102) may be between about 5 nanometer (nm) and about 25 nm, and a thickness of the n-type work function layer (e.g., second work function metal 1104) may be between about 5 nm and about 25 nm, as another example.

Next, the glue metal 1106 is formed over the second work function metal 1104. The glue metal 1106 functions as an adhesion layer between the underlying layer (e.g., 1104) and a subsequently formed gate electrode material over the glue metal 1106. The glue metal 1106 may be formed of a suitable material, such as titanium nitride, using a suitable deposition method such as CVD, PVD, ALD, or the like. A thickness of the glue metal 1106 may be between about 5 nanometer (nm) and about 25 nm, as an example.

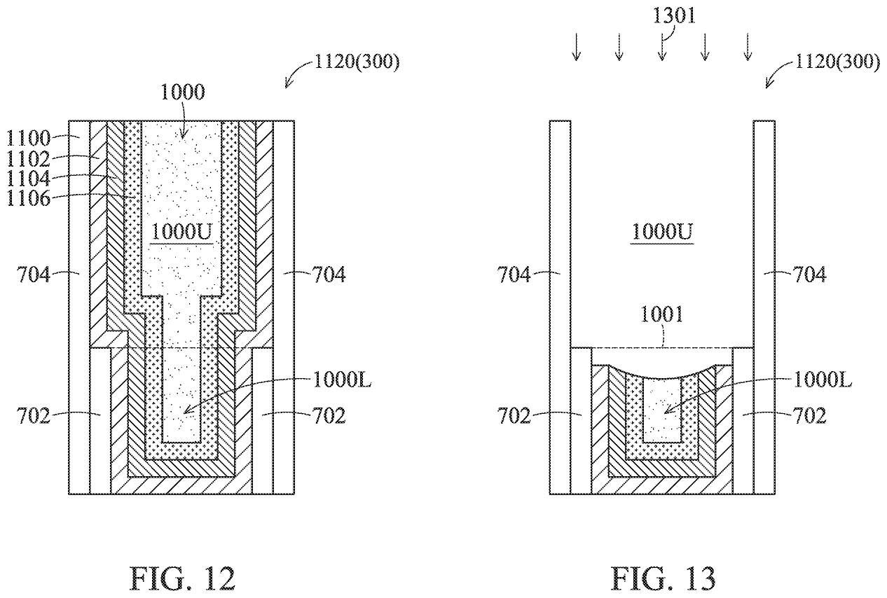

FIGS. 12-17 illustrate subsequent processing operations to form the metal gate structures of the FinFET device 300. For simplicity, FIGS. 12-16 each illustrate only a portion of the FinFET device 300. In particular, FIG. 12-16 each illustrate a zoomed-in (enlarged) view of a region 1120 in FIG. 11. For example, FIG. 12 shows the region 1120 of FIG. 11 upon the glue metal 1106 being formed.

Corresponding to operation 220 of FIG. 2, FIG. 13 is a cross-sectional view of the FinFET device 300 in which respective portions of the gate dielectric 1100, the first work function metal 1102, the second work function metal 1104, and the glue metal 1106 are removed at one of the various stages of fabrication.

In various embodiments, the gate dielectric 1100, the first work function metal 1102, the second work function metal 1104, and the glue metal 1106 may be patterned by an etching process 1301 to remove their respective portions. As shown in the example of FIG. 13, the respective portions in the upper trench 1000U may be removed. Further, the gate dielectric 1100, the first work function metal 1102, the second work function metal 1104, and the glue metal 1106 may also be recessed in the lower trench 1000L.

The etching process 1301 may be a dry etching process. For example, the etching process 1301 can include a plasma etching process, which can have a certain amount of anisotropic characteristic. In such a plasma etching process (including radical plasma etching, remote plasma etching, and other suitable plasma etching processes), etchant gas sources such as chlorine (Cl₂), boron trichloride (BCl₃), and other suitable gas sources and combinations thereof can be used with passivation gases such as nitrogen (N₂), oxygen (O₂), carbon dioxide (CO₂), sulfur dioxide (SO₂), carbon monoxide (CO), and other suitable passivation gases and combinations thereof. Moreover, the gas sources and/or the passivation gases can be diluted with gases such as argon (Ar), helium (He), neon (Ne), and other suitable dilutive gases and combinations thereof to pattern the gate dielectric 1100, the first work function metal 1102, the second work function metal 1104, and the glue metal 1106.

As a non-limiting example, a source power of about 4000 watts to about 1200 watts, a bias power of about 0 watts to about 100 watts, a pressure of about 1 millitorr to about 200 millitorr, and an etchant/passivation gas flow of about 0 standard cubic centimeters per minute to 400 standard cubic centimeters per minute (SCCM) may be used in the etching process 1301. For instance, at least one of the following flow rates may be used: boron trichloride in the flow rate from about 0 SCCM to about 400 SCCM, chlorine in the flow rate from about 0 SCCM to about 400 SCCM, or oxygen in the flow rate from about 0 SCCM to about 10 SCCM. However, it is noted that source powers, bias powers, pressures, and flow rates outside of these ranges are also contemplated.

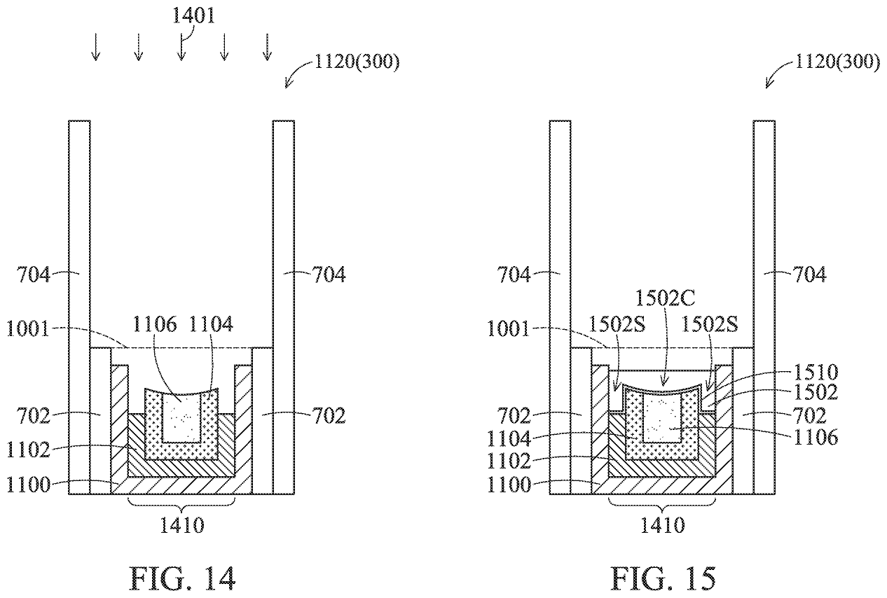

Corresponding to operation 222 of FIG. 2, FIG. 14 is a cross-sectional view of the FinFET device 300 in which one of the first work function metal 1102 or the second work function metal 1104 is selectively etched at one of the various stages of fabrication.

In various embodiments, an etching process 1401 can be performed to etch only one of the first work function metal 1102 or the second work function metal 1104. As shown in the example of FIG. 14, the first work function metal 1102 is recessed, and the second work function metal 1104 remains substantially intact. In some embodiments, the gate dielectric 1100 and the glue metal 1106 may also remain substantially intact during the etching process 1401. Consequently, the first work function metal 1102 has a top surface recessed from other top surfaces of the gate dielectric 1100, the second work function metal 1104, and the glue metal 1106 with a depth. The resultant first work function metal 1102 and second work function metal 1104 may sometimes be collectively referred to as an active (e.g., metal) gate structure 1410. In some embodiments, the metal gate structure 1410 can include the resultant gate dielectric 1100.

In the embodiment where the first work function metal 1102 has the p-type and the second work function metal 1104 has the n-type, the etching process 1401 may include a wet etching process that selectively etches the first work function metal 1102, while leaving the second work function metal 1104 substantially intact. For instance, such a wet etching process can include at least one of the following etchant solutions:APM (a mixture of ammonium hydroxide (NH₄OH), peroxide, and DI water in a ratio from about 1:1:120 to about 1:1:5), HPM (a mixture of hydrochloric acid (HCl), peroxide, and DI water in a ratio from about 1:1:120 to about 1:1:5), or diluted peroxide (in a ratio from about 1:120 to about 1:5). In the embodiment where the first work function metal 1102 has the n-type and the second work function metal 1104 has the p-type, the etching process 1401 may include a dry or wet etching process that selectively etches the first work function metal 1102, while leaving the second work function metal 1104 substantially intact. For instance, such a dry etching process can include a plasma etching process using etchant gas sources such as chlorine (Cl₂) and/or boron trichloride (BCl₃) together with passivation gas such as oxygen (O₂); and such a wet etching process can include at least one of the following etchant solutions:diluted hydrofluoric acid (HF) (in a ratio from about 1:100 to about 1:2000) or diluted ammonium hydroxide (NH₄OH) (in a ratio from about 1:5 to about 1:2000).

Corresponding to operation 224 of FIG. 2, FIG. 15 is a cross-sectional view of the FinFET device 300 including a gate electrode 1502 at one of the various stages of fabrication.

Following recessing the first work function metal 1102, an electrode metal is deposited over the metal gate structure 1410 to form the gate electrode 1502. In some embodiments, the gate electrode 1502 can follow the dimensions and profiles of the metal gate structure 1410. Specifically, the gate electrode 1502 can have side portions 1502S extending from a top surface of the gate electrode 1502 toward the substrate/fin with a relatively longer distance and central portion 1502C extending from a top surface of the gate electrode 1502 toward the substrate/fin with a relatively shorter distance, as shown in the example of FIG. 15. Such a profile may sometimes be referred to as a tiger tooth profile. Alternatively stated, an interface (e.g., 1510) between the metal gate structure 1410 and the gate electrode 1502 may also present such a tiger tooth profile. Further, although the gate electrode 1502 is formed to have its top surface positioned below the symbol interface 1001 (i.e., the top surface of the first gate spacers 702), it should be understood that the top surface of gate electrode 1502 may be aligned with or positioned above the interface 1001.

The electrode metal of gate electrode 1502 may include a suitable metal, such as tungsten (W), formed by a suitable method, such as PVD, CVD, electroplating, electroless plating, or the like. Besides tungsten, other suitable material, such as copper (Cu), gold (Au), cobalt (Co), combinations thereof, multi-layers thereof, alloys thereof, or the like, may also be used as the gate electrode 1502.

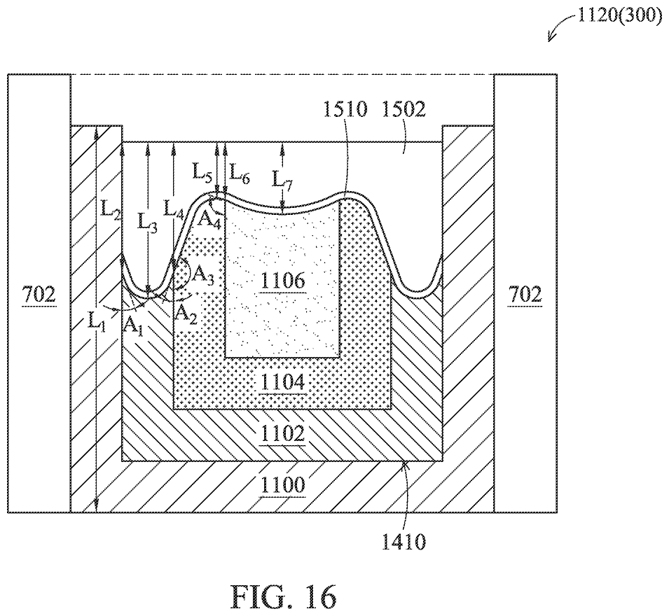

To illustrate some of example dimensions of the tiger tooth profile of the interface or gate electrode 1502, a further zoomed-in cross-sectional view including the metal gate structure 1410 and the gate electrode 1502, with multiple annotated dimension measurements, is shown in FIG. 16.

For example, the gate dielectric 1100 may have a height (“L₁”), measured from its top surface to its bottom surface (a top surface of the underlying fin 404), that is in a range from about 8 nm to about 20 nm. The gate electrode 1502 may have a sidewall with a height (“L₂”), measured from its top surface to a highest point at the interface between the gate dielectric 1100 and the first work function metal 1102, that is in a range from about 0 nm to about 13 nm. The gate electrode 1502 may have a height (“L₃”) on its side portion (e.g., a lowest point of the first work function metal 1102) that is in a range from about 0 nm to about 18 nm. The gate electrode 1502 may have another height (“L₄”), measured from its top surface to a point at the interface between the first work function metal 1102 and the second work function metal 1104, that is in a range from about 0 nm to about 13 nm. The gate electrode 1502 may have another height (“L₅”), measured from its top surface to a highest point of the second work function metal 1104, that is in a range from about 0 nm to about 10 nm. The gate electrode 1502 may have yet another height (“L₆”), measured from its top surface to a point at the interface between the second work function metal 1104 and the glue metal 1106, that is in a range from about 0 nm to about 10 nm. The gate electrode 1502 may have yet another height (“L₇”), measured from its top surface to a lowest point of the glue metal 1106, that is in a range from about 0 nm to about 10 nm. As such, a ratio of a first height (or a first extending depth/distance, e.g., L₃) to a second height (or a second extending depth/distance, e.g., L₅/L₆/L₇) of the tiger tooth profile is greater than 1, e.g., about 1.8, in some embodiments.

Further in FIG. 16, an angle (“A₁”) between the sidewall of the gate dielectric 1100 and a portion of the top surface of the first work function meal 1102 is in a range of from about 0 degrees to about 45 degrees. An angle (“A₂”) a portion of the top surface of the first work function meal 1102 and the interface between the first and second work function metals is in a range of from about 0 degrees to about 45 degrees. An angle (“A₃”) a portion of the top surface of the second work function meal 1104 and the interface between the first and second work function metals is in a range of from about 135 degrees to about 180 degrees. An angle (“A₄”) a portion of the top surface of the second work function meal 1104 and the interface between the second work function metal and the glue metal is in a range of from about 45 degrees to about 135 degrees.

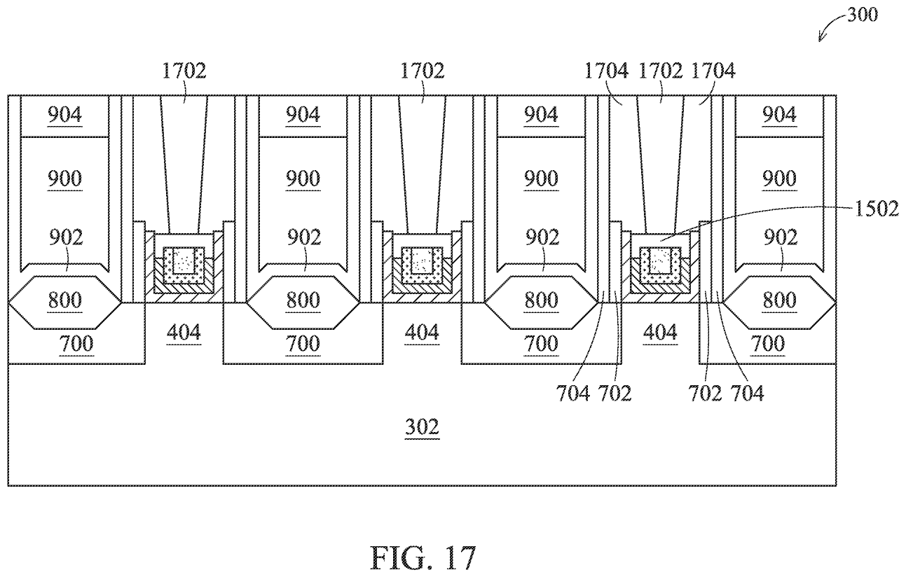

Corresponding to operation 226 of FIG. 2, FIG. 17 is a cross-sectional view of the FinFET device 300 in which one or more gate contacts 1702 are formed at one of the various stages of fabrication.

As shown, the gate contact 1702 is formed in (e.g., to extend through) a dielectric material 1704 to electrically couple to the gate electrode 1502. In some embodiments, the dielectric material 1704 is first deposited in the remaining portion of the gate trench 1000. The dielectric material 1704 (e.g., silicon oxide, silicon nitride, a low-k dielectric material, or the like) is formed in the gate trench 1000, using a suitable formation method such as PVD, CVD, or the like. Next, a contact opening is then formed in the dielectric material to expose the corresponding gate electrode 1502, using, e.g., photolithography and etching. Once the contact opening is formed, a barrier layer, a seed layer, and a fill metal can be formed successively in the contact opening to form the corresponding gate contact 1702.

The barrier layer includes an electrically conductive material such as titanium nitride, although other materials, such as tantalum nitride, titanium, tantalum, or the like, may alternatively be utilized. The barrier layer may be formed using a CVD process, such as PECVD. However, other alternative processes, such as sputtering, metal organic chemical vapor deposition (MOCVD), or ALD, may alternatively be used.

The seed layer is formed over the barrier layer. The seed layer may include copper, titanium, tantalum, titanium nitride, tantalum nitride, the like, or a combination thereof, and may be deposited by ALD, sputtering, PVD, or the like. In some embodiments, the seed layer is a metal layer, which may be a single layer or a composite layer comprising a plurality of sub-layers formed of different materials. For example, the seed layer may include a titanium layer and a copper layer over the titanium layer.

The fill metal is deposited over the seed layer, and fills the remaining portion of the contact opening. The fill metal may be a metal-containing material such as copper (Cu), aluminum (Al), tungsten (W), the like, combinations thereof, or multi-layers thereof, and may be formed by, e.g., electroplating, electroless plating, or other suitable method. After the formation of the fill metal, a planarization process, such as a CMP, may be performed to remove the excess portions of the barrier layer, the seed layer, and the fill metal, which excess portions are over the upper surface of the dielectric layer 904 (referring again to FIG. 11). The resulting remaining portions of the barrier layer, the seed layer, and the fill metal thus form the gate contact 1702.

In one aspect of the present disclosure, a semiconductor device is disclosed. The semiconductor device includes a semiconductor fin. The semiconductor device includes first spacers over the semiconductor fin. The semiconductor device includes a metal gate structure, over the semiconductor fin, that is sandwiched at least by the first spacers. The semiconductor device includes a gate electrode contacting the metal gate structure. An interface between the metal gate structure and the gate electrode has its side portions extending toward the semiconductor fin with a first distance and a central portion extending toward the semiconductor fin with a second distance, the first distance being substantially less than the second distance.

In another aspect of the present disclosure, a semiconductor device is disclosed. The semiconductor device includes a semiconductor channel. The semiconductor device includes a metal gate structure disposed over the semiconductor channel. The semiconductor device includes a gate electrode having a bottom surface contacting an upper surface of the metal gate structure. The gate electrode has its side portions extending from its top surface toward the semiconductor fin with a first depth and a central portion extending from its top surface toward the semiconductor fin with a second depth, the first depth being substantially greater than the second depth.

In yet another aspect of the present disclosure, a method for fabricating semiconductor devices is disclosed. The method includes forming a gate trench over a semiconductor channel, the gate trench being surrounded by gate spacers. The method includes depositing a first work function metal in the gate trench. The method includes depositing a second work function metal over the first work function metal in the gate trench. The method includes etching the first work function metal while leaving the second work function metal substantially intact to form a metal gate structure. The method includes depositing an electrode metal in the gate trench to form a gate electrode in contact with the metal gate structure.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a semiconductor fin;
first spacers over the semiconductor fin;
a metal gate structure, over the semiconductor fin, that is sandwiched at least by the first spacers; and
a gate electrode contacting the metal gate structure;
wherein an interface between the metal gate structure and the gate electrode has its side portions extending toward the semiconductor fin with a first distance and a central portion extending toward the semiconductor fin with a second distance, the first distance being substantially less than the second distance.

2. The semiconductor device of claim 1, wherein the metal gate structure comprises:
a first work function metal; and
a second work function metal.

3. The semiconductor device of claim 2, wherein the side portions are, in part, formed by respective top surfaces of the first work function metal, and the central portion is, in part, is formed by the second work function metal.

4. The semiconductor device of claim 2, wherein the first work function metal has a p-type work function metal, and the second work function metal has an n-type work function metal.

5. The semiconductor device of claim 2, wherein the first work function metal has a first U-shaped profile, and the second work function metal has a second U-shaped profile at least partially enclosed by the first U-shaped profile.

6. The semiconductor device of claim 1, wherein the gate electrode includes a first height extending from the side portions to a top surface of the gate electrode, and a second height extending from the central portion to the top surface of the gate electrode, and wherein the first height is substantially greater than the second height.

7. The semiconductor device of claim 6, wherein a ratio of the second height to the first height is about 1.8.

8. The semiconductor device of claim 1, wherein the metal gate structure comprises a plurality of work functions metals that have respectively different conductive type, and the gate electrode includes tungsten.

9. The semiconductor device of claim 1, further comprising:
second spacers over the semiconductor fin, the second spacers extending farther from the semiconductor fin than the first spacers;
wherein the first spacers are further sandwiched by the second spacers.

10. The semiconductor device of claim 9, wherein the gate electrode has its sidewalls in direct contact with inner sidewalls of the first spacers, respectively.

11. A semiconductor device, comprising:
a semiconductor fin;
a metal gate structure disposed over the semiconductor fin; and
a gate electrode having a bottom surface contacting an upper surface of the metal gate structure;
wherein the gate electrode has its side portions extending from its top surface toward the semiconductor fin with a first depth and a central portion extending from its top surface toward the semiconductor fin with a second depth, the first depth being substantially greater than the second depth.

12. The semiconductor device of claim 11, wherein the metal gate structure comprises:
a first work function metal having a first U-shaped profile; and
a second work function metal having a second U-shaped profile;
wherein the second work function metal is at least partially enclosed by the first work function metal.

13. The semiconductor device of claim 12, wherein the first depth is measured from the top surface of the gate electrode to a top surface of the first work function metal, and the second depth is measured from the top surface of the gate electrode to a top surface of the second work function metal.

14. The semiconductor device of claim 12, wherein the first work function metal and second work function metal have respectively different conductive types.

15. The semiconductor device of claim 11, wherein a ratio of the second depth to the first depth is about 1.8.

16. The semiconductor device of claim 11, further comprising first gate spacers sandwiching the metal gate structure and the gate electrode.

17. The semiconductor device of claim 16, wherein the gate electrode has its sidewalls in direct contact with inner sidewalls of the first gate spacers, respectively.

18. The semiconductor device of claim 16, further comprising:
second gate spacers further sandwiching the first gate spacers;
wherein the second gate spacers extend farther from the semiconductor fin than the first gate spacers.

19. A method for fabricating semiconductor devices, comprising:
forming a gate trench over a semiconductor fin, the gate trench being surrounded by gate spacers;
depositing a first work function metal in the gate trench;
depositing a second work function metal over the first work function metal in the gate trench;
etching the first work function metal while leaving the second work function metal substantially intact to form a metal gate structure; and
depositing an electrode metal in the gate trench to form a gate electrode in contact with the metal gate structure.

20. The method of claim 19, wherein the first work function metal and second work function metal have respectively different conductive types.
